(19) United States
(12) Patent Application Publication
(10) Pub. No.: US 2021/0047730 A1
(43) Pub. Date: Feb. 18, 2021

(54) CHAMBER CONFIGURATIONS FOR CONTROLLED DEPOSITION

(71) Applicant: Applied Materials, Inc., Santa Clara, CA (US)

(72) Inventors: Sai Susmita Addepalli, San Jose, CA (US); Yue Chen, Sunnyvale, CA (US); Zhijun Jiang, San Jose, CA (US); Shailendra Srivastava, Fremont, CA (US); Nikhil Sudhindrarao Jorapur, Sunnyvale, CA (US); Daemian Raj Benjamin Raj, Fremont, CA (US); Greg Chichkanoff, Gilroy, CA (US); Qiang Ma, Cupertino, CA (US); Abhigyan Keshri, Sunnyvale, CA (US); Xinhai Han, Santa Clara, CA (US); Ganesh Balasubramanian, Fremont, CA (US); Deenesh Padhi, Sunnyvale, CA (US)

(73) Assignee: Applied Materials, Inc., Santa Clara, CA (US)

(21) Appl. No.: 16/986,438

(22) Filed: Aug. 6, 2020

Related U.S. Application Data
(60) Provisional application No. 62/886,078, filed on Aug. 13, 2019.

(51) Int. Cl. C23C 16/458; H01L 21/02; H01J 37/32; C23C 16/455; C23C 16/52

(52) U.S. Cl. CPC C23C 16/4581; H01L 21/02274; H01J 37/32715; H01J 2237/3321; C23C 16/45565; C23C 16/52; H01J 37/32449

(57) ABSTRACT

Exemplary semiconductor processing chambers may include a showerhead. The chambers may also include a substrate support characterized by a first surface facing the showerhead. The first surface may be configured to support a semiconductor substrate. The substrate support may define a recessed pocket centrally located within the first surface. The recessed pocket may be defined by an outer radial wall characterized by a height from the first surface within the recessed pocket that is greater than or about 150% of a thickness of the semiconductor substrate.

### CROSS-REFERENCE TO RELATED APPLICATIONS

The present application claims the benefit of, and priority to U.S. Provisional Patent Application No. 62/886,078, filed Aug. 13, 2019, the contents of which are hereby incorporated by reference in their entirety for all purposes.

### TECHNICAL FIELD

The present technology relates to semiconductor processes and chamber components. More specifically, the present technology relates to modified components to control material deposition.

### BACKGROUND

Integrated circuits are made possible by processes which produce intricately patterned material layers on substrate surfaces. Producing patterned material on a substrate requires controlled methods of formation and removal of exposed material. Stacked memory, such as vertical or 3D NAND, may include the formation of a series of alternating layers of dielectric materials through which a number of memory holes or apertures may be etched. The formation process may include many layers of deposition. Thickness uniformity across a deposited film may impact subsequent operations. Additionally, characteristics of edge deposition may impact film peeling, as well as contamination.

Thus, there is a need for improved systems and methods that can be used to produce high quality devices and structures. These and other needs are addressed by the present technology.

### SUMMARY

Exemplary semiconductor processing chambers may include a showerhead. The chambers may also include a substrate support characterized by a first surface facing the showerhead. The first surface may be configured to support a semiconductor substrate. The substrate support may define a recessed pocket centrally located within the first surface. The recessed pocket may be defined by an outer radial wall characterized by a height from the first surface within the recessed pocket that is greater than or about 150% of a thickness of the semiconductor substrate.

In some embodiments, the outer radial wall may be characterized by a height from the first surface within the recessed pocket that is less than or about 500% of a thickness of the semiconductor substrate. The outer radial wall may be characterized by an angle relative to the first surface of the substrate support of less than or about 90°. The outer radial wall may be characterized by an angle relative to the first surface of the substrate support of greater than or about 60°. The outer radial wall may be characterized by a radius that is less than or about 102% of a radius of the semiconductor substrate. The outer radial wall may be formed by the substrate support or an annular member extending about the substrate support. The annular member may be configured to extend radially inward past an outer radius of the semiconductor substrate. The annular member may extend inward a distance of less than or about 2% of the outer radius of the semiconductor substrate. The showerhead may define a plurality of apertures through the showerhead, and the showerhead may be configured to operate as a plasma-generating electrode. A subset of the plurality of apertures may be characterized by a cylindrical shape through the showerhead. A subset of the plurality of apertures are at least partially characterized by a flare extending to a first surface of the showerhead, and the first surface of the showerhead may face the first surface of the substrate support.

Some embodiments of the present technology may also encompass methods of controlling deposition uniformity. The methods may include depositing one or more layers of material on a semiconductor substrate within a semiconductor processing chamber. The semiconductor processing chamber may include a showerhead and a substrate support. The showerhead may define a plurality of apertures through the showerhead, and at least a subset of the apertures may be characterized by a cylindrical shape through the showerhead. The methods may include identifying a region of non-uniformity in film thickness of the one or more layers of material. The methods may include producing a revised showerhead defining a plurality of apertures through the showerhead. The producing may include adjusting apertures of the showerhead associated with deposition at the region of non-uniformity on the semiconductor substrate. The methods may include depositing one or more layers of the material on a semiconductor substrate within a semiconductor processing chamber including the revised showerhead. The one or more layers of material may be characterized by increased uniformity relative to the region of non-uniformity identified.

In some embodiments, the region of non-uniformity may be characterized by a reduced film thickness. Adjusting apertures of the showerhead may include increasing an aperture density at a radius of the showerhead associated with deposition at the region of non-uniformity on the semiconductor substrate. Increasing an aperture density at a radius of the showerhead associated with deposition at the region of non-uniformity on the semiconductor substrate may include at least doubling the number of apertures about the radius of the showerhead. The region of non-uniformity may be characterized by a reduced film thickness. Adjusting apertures of the showerhead may include exchanging apertures characterized by a cylindrical shape with apertures characterized by a flare extending to a first surface of the showerhead. The first surface of the showerhead may be configured to face the first surface of the substrate support, at a radius of the showerhead associated with deposition at the region of non-uniformity on the semiconductor substrate. The region of non-uniformity in film thickness of the one or more layers of material may be located proximate an edge of the semiconductor substrate.

Some embodiments of the present technology may encompass semiconductor processing chambers. The chambers may include a showerhead defining a plurality of apertures through the showerhead. At least a subset of the apertures may be characterized by a cylindrical shape through the showerhead. The chambers may also include a substrate support characterized by a first surface facing the showerhead. The first surface may be configured to support a semiconductor substrate. The substrate support may define a recessed pocket centrally located within the first surface. The recessed pocket may be defined by an outer radial wall characterized by an angle relative to the first surface of the substrate support of less than or about 90°.

In some embodiments, the outer radial wall may be characterized by an angle relative to the first surface of the substrate support of greater than or about 60°. The outer radial wall may be characterized by a height from the first surface within the recessed pocket greater than or about 150% of a thickness of the semiconductor substrate. The outer radial wall may be characterized by a height from the first surface within the recessed pocket that is less than or about 500% of a thickness of the semiconductor substrate. A subset of the plurality of apertures may be at least partially characterized by a flare extending to a first surface of the showerhead, and the first surface of the showerhead may face the first surface of the substrate support.

Such technology may provide numerous benefits over conventional systems and techniques. For example, the systems may limit or minimize deposition on edge regions of a substrate, which may improve peeling and contaminant production. Additionally, the operations of embodiments of the present technology may produce components that can improve deposition uniformity compared to conventional systems. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows a schematic cross-sectional view of an exemplary processing chamber according to some embodiments of the present technology.

FIGS. 3A-3C show schematic cross-sectional views of exemplary substrate supports according to some embodiments of the present technology.

FIG. 4 shows a schematic cross-sectional view of an exemplary showerhead according to some embodiments of the present technology.

FIG. 5 shows exemplary operations in a method of controlling deposition uniformity according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During 3D NAND processing, stacks of placeholder layers and dielectric materials may form the inter-electrode dielectric or inter-poly dielectric (“IPD”) layers, which may include alternating layers of oxide and nitride or oxide and polysilicon, as some examples. These placeholder layers may have a variety of operations performed to place structures before fully removing the material and replacing it with metal. The IPD layers are often formed overlying a conductor layer, such as polysilicon, for example. When the memory holes are formed, apertures may extend through all of the alternating layers of material before accessing the polysilicon or other material substrate. Subsequent processing may form a staircase structure for contacts, and may also exhume the placeholder materials laterally.

The processes for forming the IPD layers may include depositing a number of alternating layers of materials, which can number in the tens or hundreds of layers. Among other challenges with these film formations, uniformity of deposition may impact a number of operations. For example, non-uniform thicknesses within a layer may translate layer-to-layer through the stack, which may impact downstream processes. Additionally, as electronic structures are extended further out on substrates, edge uniformity becomes increasingly important. Another challenge with deposition on the edge of the substrate may be related to the heater or substrate support on which the substrate or wafer is seated. The radial, or lateral, edge of a substrate may be characterized by a bevel, or a non-vertical wall. Characteristics of the substrate support may impact plasma or flow properties at this sidewall of the substrate, which may affect deposition.

Conventional technologies have struggled with uniformity and control during the formation processes, which can lead to non-uniformities across a substrate. As manufacturers attempt to extend the useable area across a substrate, these non-uniformities may limit additional useable area. Additionally, some conventional processing chamber substrate supports may poorly control edge deposition, which can lead to film peeling at the bevel of the substrate causing contamination in downstream processing. The present technology overcomes these issues by utilizing a heater or substrate support that produces a pocket in which the substrate is seated, and that can control film formation at edge and bevel regions of a substrate. Additionally, some embodiments of the present technology incorporate conical apertures or increased aperture density at particular locations through the showerhead, which may be associated with regions on a substrate where film thickness non-uniformities may occur.

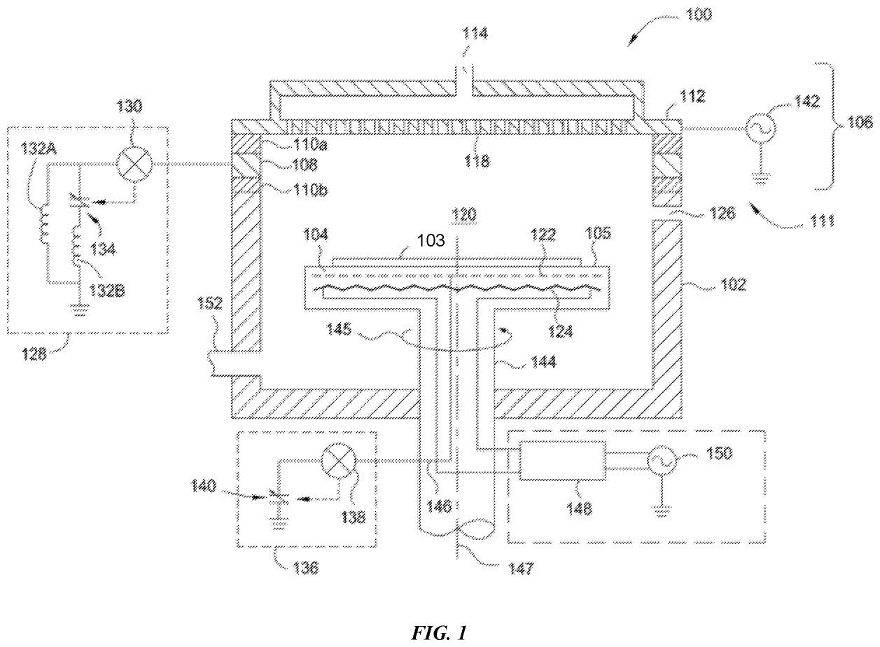

FIG. 1 shows a cross-sectional view of an exemplary processing chamber system 100 according to some embodiments of the present technology. The figure may illustrate an overview of a system incorporating one or more aspects of the present technology, and/or which may perform one or more operations according to embodiments of the present technology. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

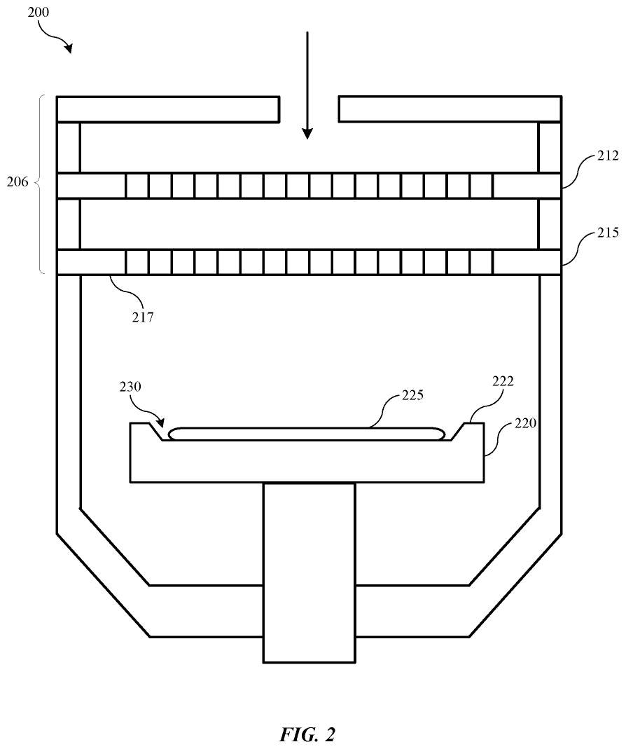

FIG. 2 shows a schematic cross-sectional view of an exemplary processing chamber 200 according to some embodiments of the present technology. Chamber 200 may include any of the aspects of chamber system 100 described above, and may provide further foundation for aspects of the present technology described below. Chamber 200 may include a lid assembly 206 including one or more features, components, or characteristics described above. For example, the lid assembly may include a gas distributor 212, which may include a blocker plate. The system may also include an additional showerhead 215 in some embodiments, which may operate as a plasma-generating electrode either alone, or in conjunction with other lid assembly components. As will be described further below, while the gas distributor or blocker plate may operate to produce a more uniform distribution of precursors within the chamber, showerhead 215 may include one or more features configured to modify precursor distribution or plasma generation. Exemplary showerheads 215 may be characterized by a first surface 217, which may face a substrate support, and may at least partially define a processing region within chamber 200.

Chamber 200 may also include a substrate support 220, or heater, which may maintain a substrate 225 during film formation or other processing. The substrate support 220 may include one or more incorporated heating elements, one or more incorporated cooling elements, one or more incorporated plasma-generation elements, as well as any number of other components or materials described previously, or which may be otherwise incorporated with substrate support 220 to facilitate operation or processing within chamber 200. Similar to showerhead 215, substrate support 220 may be characterized by a first surface 222, which may face showerhead 215, and may at least partially define the processing region within chamber 200, such as from below while showerhead 215 may define the processing region from above, for example. As will be described further below, substrate support 220 may define a pocket 230 within the first surface 222 of substrate support 220. Substrate 225 may be seated within this pocket during processing.

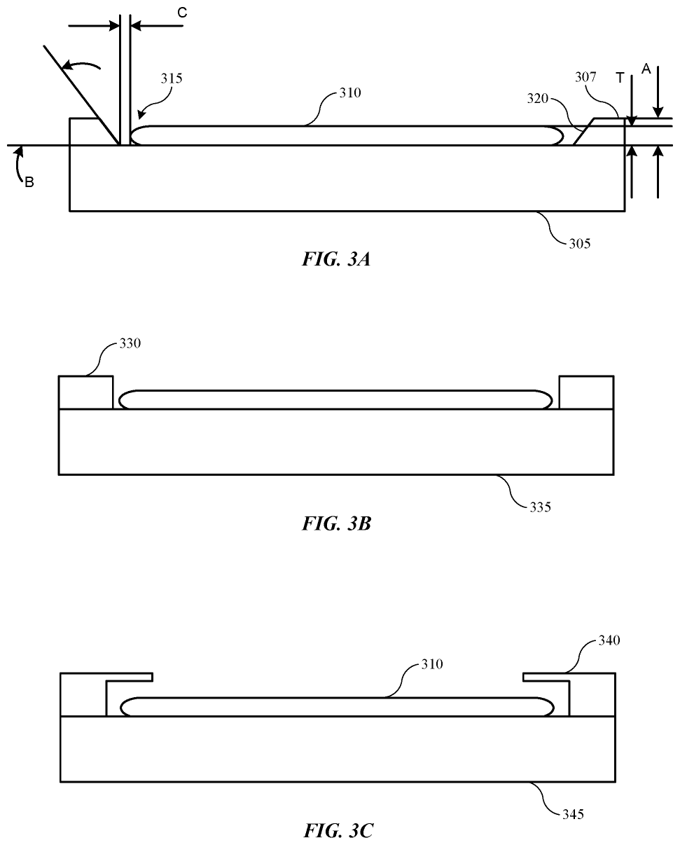

Characteristics of pocket 230 may impact film deposition, and which may contribute to film peeling and contamination as previously described. FIGS. 3A-3C show schematic cross-sectional views of portions of exemplary substrate supports according to some embodiments of the present technology. The substrate supports may include any characteristics, components, or configurations as previously described. The substrate supports may have characteristics that control or limit film deposition on far edge or bevel regions of the substrate. Substrates may be characterized by regions on which processing occurs. For example, a substrate may have a middle and an edge region in which processing may occur. Outside of the viable area may be a far edge region, which may extend to a lateral edge that may be characterized by a bevel or non-vertical wall based on substrate formation or development. The interface between the edge and far edge region may depend on manufacturer preference, but may be limited to a percentage of the overall substrate diameter. As one non-limiting example, for a 300 mm wafer or substrate, the far edge region, which may be scrapped after dicing, may be only 1% of the wafer diameter, such as 3 mm. As manufacturers seek to extend the viable area on a substrate, this far edge region may be reduced to 0.5% or less of the substrate diameter. By reducing the far edge region on the substrate in this way, the viable area for processing may be increased by 1%-2% or more, which when factored into the number of substrates processed each year, can account for a substantial increase in revenue.

The bevel at a radial edge, or lateral edge depending on substrate geometry, may impact deposition uniformity as well as impact film stability. This may be further compounded based on an interaction between the edge of the substrate and the substrate support. For example, a planar substrate support may allow generated plasma to extend about the edge of the substrate, which may increase deposition at the bevel and exacerbate film peeling issues. By creating a pocket within which the substrate may be seated, plasma encroachment at the substrate edge may be controlled.

As shown in FIG. 3A, substrate support 305 may be characterized by a first surface 307 on which a substrate 310 may be seated. Within first surface 307 may be defined a pocket 315, which may be recessed within first surface 307 as illustrated, or may be formed about first surface 307 as will be further described below. Pocket 315 may be centrally located within the first surface 307, and may be defined by an outer radial wall 320. Although the disclosure will routinely discuss curved shapes, such as may be characterized by a radius or diameter, it is to be understood that other geometric configurations including rectilinear components or configurations are similarly encompassed by the present technology.

Outer radial wall 320 may be characterized by a number of characteristics that may affect plasma generation as well as deposition characteristics of the present technology. By defining a pocket and/or outer radial wall according to embodiments of the present technology, film deposition at the bevel may be controlled, while limiting an impact on edge deposition, which may affect device production. For example, outer radial wall 320 may be characterized by a radius, such as from a central axis through the substrate support 305 and/or substrate 310, outer radial wall 320 may be characterized by an angle of slope, and outer radial wall 320 may be characterized by a height from the first surface within the recessed pocket 315. One or more of these characteristics may be adjusted to affect deposition characteristics.

As noted, outer radial wall 320 may be characterized by a height from the first surface within the recessed pocket 315, which is shown as dimension A in FIG. 3A. In some embodiments, this height may be relative to a thickness of substrate 310 or wafer to be processed. For example, prior to processing, substrate 310 may be characterized by a thickness T as illustrated, and in some embodiments, dimension A, or the height of the outer radial wall 320, may be greater than or about the thickness T of the substrate 310. When dimension A is less than or equal to the thickness T of a substrate to be processed, deposition at a radial edge of the substrate, such as at the bevel, may cause film peeling and contamination issues as previously described. Without being bound to any particular theory, this may relate to plasma intrusion or access about the bevel during processing.

As the height of the outer radial wall 320 increases above the thickness T of the substrate to be processed, deposition at the bevel, and the issues this may cause, may be controlled or limited. Accordingly, in some embodiments the outer radial wall may be characterized by a height from the first surface within the recessed pocket, such as dimension A as illustrated, greater than or about 120% of a thickness of the semiconductor substrate, and may be characterized by a height greater than or about 130% of the thickness, greater than or about 150% of the thickness, greater than or about 175% of the thickness, greater than or about 200% of the thickness, greater than or about 225% of the thickness, greater than or about 250% of the thickness, greater than or about 275% of the thickness, greater than or about 300% of the thickness, greater than or about 325% of the thickness, greater than or about 350% of the thickness, greater than or about 375% of the thickness, greater than or about 400% of the thickness, greater than or about 425% of the thickness, greater than or about 450% of the thickness, greater than or about 475% of the thickness, greater than or about 500% of the thickness, greater than or about 525% of the thickness, greater than or about 550% of the thickness, greater than or about 575% of the thickness, greater than or about 600% of the thickness, or more.

As the height of the outer radial wall increases, the effects on film formation may creep inward, affecting an edge region of the substrate, and reducing viable area for production. Accordingly, in some embodiments the outer radial wall may be characterized by a height from the first surface within the recessed pocket, such as dimension A as illustrated, less than or about 750% of a thickness of the semiconductor substrate, and may be characterized by a height less than or about 725% of the thickness, less than or about 700% of the thickness, less than or about 675% of the thickness, less than or about 650% of the thickness, less than or about 625% of the thickness, less than or about 600% of the thickness, less than or about 575% of the thickness, less than or about 550% of the thickness, less than or about 525% of the thickness, less than or about 500% of the thickness, or less. By maintaining the height of the outer radial wall within a range, film peeling may be reduced, while effects on the viable edge region may be limited or prevented.

An angle or slope of the outer radial wall may also impact deposition at the bevel. Again, without being bound to any particular theory, as an amount of slope increases from the substrate, a gap between the bevel of the substrate and the outer radial wall may increase, and may increase plasma generation about the bevel of the substrate. Consequently, in some embodiments the angle B of the slope of the sidewall may be maintained greater than or about 60°, and may be maintained greater than or about 65°, greater than or about 70°, greater than or about 75°, greater than or about 80°, greater than or about 85°, greater than or about 90°, or more. Again, as angle continues to increase, reductions in deposition may creep past far edge regions into edge regions, which may affect device production. Accordingly, in some embodiments the angle B of the slope of the sidewall may be maintained less than or about 120°, and may be maintained less than or about 115°, less than or about 110°, less than or about 105°, less than or about 100°, less than or about 95°, less than or about 90°, or less. By maintaining the angle of the outer radial wall within a range, film peeling may again be reduced, while effects on the viable edge region may be limited or prevented.

A distance the outer radial wall extends beyond the dimensions of the substrate may also impact deposition at the bevel. Again, without being bound to any particular theory, as a gap between the substrate and the outer radial wall increases, such as illustrated as dimension C in FIG. 3A, plasma generation about the bevel may occur, which may increase deposition and film effects. Consequently, in some embodiments the outer radial wall may be characterized by a radius or lateral dimension that is less than or about 110% of a radius of the substrate, and may be characterized by a radius that is less than or about 109% of the radius of the substrate, less than or about 108% of the radius of the substrate, less than or about 107% of the radius of the substrate, less than or about 106% of the radius of the substrate, less than or about 105% of the radius of the substrate, less than or about 104% of the radius of the substrate, less than or about 103% of the radius of the substrate, less than or about 102% of the radius of the substrate, less than or about 101% of the radius of the substrate, or less. However, in order to limit interactions between the substrate and the outer radial wall during delivery and retrieval of the substrate, the outer radial wall may be characterized by a radius or lateral dimension that is at least about 100.1% of the radius of the substrate. By coordinating the height, angle, and gap distance of the outer radial wall, deposition along the bevel and far edge region of the substrate can be controlled to limit or prevent peeling and contamination issues.

In some embodiments the outer radial wall may be monolithically formed as part of the substrate support, such as illustrated in FIG. 3A. In some embodiments, an additional component may be incorporated with the substrate support to form the outer radial wall. For example, as illustrated in FIG. 3B, an edge ring 330 or annulus may be coupled with a substrate support 335 to produce the pocket and define an outer radial wall about the substrate. The edge ring may be the same or a different material than the substrate support, and may be coupled by any means with the substrate support.

In some embodiments the outer radial wall may be a component that protects the bevel and/or far edge region of the substrate. As shown in FIG. 3C, an annular member 340 may sit on an outer region of the substrate support 345. As illustrated, a portion of the member may extend radially inward past an outer radius of the semiconductor substrate 310. Such a configuration may be enabled by a translating substrate support. For example, a planar or otherwise accessible substrate support may receive a substrate. The substrate support may then be lifted or raised, and may engage annular member 340 about an outer region of the substrate support. The annular member 340 may extend at least partially over the substrate 310, and may limit or prevent deposition on a bevel or far edge region.

For example, the annular member may extend inward a distance of less than or about 5% of the outer radius of the semiconductor substrate, and may extend less than or about 4.5% of the outer radius, less than or about 4.0% of the outer radius, less than or about 3.5% of the outer radius, less than or about 3.0% of the outer radius, less than or about 2.5% of the outer radius, less than or about 2.0% of the outer radius, less than or about 1.9% of the outer radius, less than or about 1.8% of the outer radius, less than or about 1.7% of the outer radius, less than or about 1.6% of the outer radius, less than or about 1.5% of the outer radius, less than or about 1.4% of the outer radius, less than or about 1.3% of the outer radius, less than or about 1.2% of the outer radius, less than or about 1.1% of the outer radius, less than or about 1.0% of the outer radius, less than or about 0.9% of the outer radius, less than or about 0.8% of the outer radius, less than or about 0.7% of the outer radius, less than or about 0.6% of the outer radius, less than or about 0.5% of the outer radius, less than or about 0.4% of the outer radius, less than or about 0.3% of the outer radius, less than or about 0.2% of the outer radius, less than or about 0.1% of the outer radius, or less.

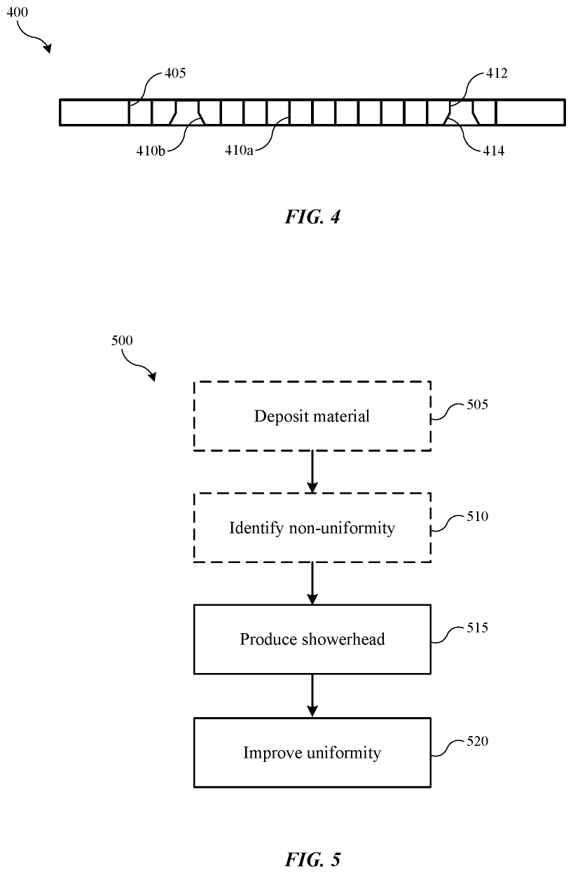

Deposition may also be controlled in one or more ways with a showerhead, such as showerhead 215 described previously. While conventional showerheads may include similar apertures across the device or may maintain a consistent pattern, the present technology may include adjusted apertures or patterns in some embodiments. FIG. 4 shows a schematic cross-sectional view of an exemplary showerhead 400 according to some embodiments of the present technology. Showerhead 400 may include any features or characteristics of any distributor described previously, and may operate as a showerhead or gas distributor noted above, including as a plasma-generating component. Showerhead 400 may be one non-limiting example of showerheads according to some embodiments of the present technology, which may include a plurality of apertures 405. Although the apertures may be of any shape, in some embodiments the apertures may be characterized by a first set of apertures 410a, which may be cylindrically-shaped apertures. The apertures may further be characterized by a second set of apertures 410b, which may be apertures characterized by a cylindrical portion 412 extending at least partly through the showerhead, and then transitioning to a flared portion 414 or conical portion extending to a first surface of the showerhead, such as a surface facing a substrate support.

The shape of the aperture may impact ion generation during plasma deposition processes, which may impact an amount of deposition at a location associated with the particular aperture. For example, although particular dimensions of the apertures may impact deposition, apertures 410b may in some embodiments provide an amount of deposition that may be at least about twice as much as a similar situated aperture 410a, and may provide an amount of deposition that may be at least about three times as much as a similar situated aperture 410a. Without being bound by any particular theory, the deposition may be associated with an increased ionization occurring through apertures 410b. Additionally, in some embodiments, an aperture density may be increased or decreased in particular regions, such as by increasing or decreasing the number of apertures 410a and/or 410b in a region of the showerhead associated with deposition non-uniformity. This specific showerhead formation may be related to an examination process for determining a suitable aperture or showerhead configuration.

FIG. 5 shows exemplary operations in a method 500 of controlling deposition uniformity according to some embodiments of the present technology. The method may be performed in one or more chambers, including any of the chambers previously described, and which may include any previously noted components. The method may include utilizing a particular showerhead in a process after identifying film uniformity issues. Method 500 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 500 may include one or more testing operations to identify film development issues, such as thickness uniformity issues, including thickness variation across a substrate. For example, method 500 may optionally include a testing operation where one or more layers of material may be deposited on a semiconductor substrate within a semiconductor processing chamber at optional operation 505. The showerhead used during the operation may include any number of aperture profiles and distributions, although at least a subset of the apertures may be characterized by a cylindrical shape through the showerhead. At optional operation 510, a region of non-uniformity in film thickness of the one or more layers of material may be identified. The identification may include in situ or ex situ identification, and the non-uniformity may include increased thickness or decreased thickness relative to one or more other regions of the substrate.

At operation 515, a revised showerhead may be produced that has an adjusted aperture profile relative to the showerhead utilized during the previous testing operations. For example, producing the showerhead may include adjusting apertures of the showerhead associated with deposition at the region of non-uniformity on the semiconductor substrate. The revised showerhead may be installed within a processing chamber, which may be or include aspects, components, or characteristics of any of the previously described chambers or components. At operation 520, a subsequent deposition of the material may be performed, such as on a subsequent substrate, where one or more layers of the material may be deposited on a semiconductor substrate within the processing chamber incorporating the revised showerhead. The one or more layers of material may be characterized by increased or improved uniformity of film thickness relative to the region of non-uniformity previously identified.

The identification and production processes may include a number of adjustments, which may be based on whether a goal is to increase or decrease deposition in a localized region. For example, as one non-limiting scenario, the region of non-uniformity may be characterized by a reduced film thickness, which may occur in some deposition processes at locations such as a center of a substrate, as well as edge regions of a substrate. An examination may identify regions having these issues, which may include many geometries, including localized areas, as well as annular regions. Adjusting the apertures for a revised showerhead in this example may include increasing an aperture density at a radial location of the showerhead, such as in an annular pattern, or between two radii of the showerhead, such as in a non-uniform pattern, associated with deposition at the region of non-uniformity on the substrate.

For example, where an annular area at a particular radial dimension about the showerhead may be characterized by reduced thickness, the number of apertures, such as the number of apertures 410a, may be increased, including doubled, tripled, or otherwise increased. Additionally, the apertures within the area or section may be exchanged in whole or in part with apertures having a profile such as 410b, which may be associated with increased deposition. In this way, particular deposition processes may be performed with increased uniformity across a surface of the substrate.

By utilizing methods and components according to embodiments of the present technology, material deposition or formation may be improved. This may increase uniformity of film thickness across a substrate, and may similarly control formation at locations across the substrate, which may include limiting or preventing deposition at a far edge and/or bevel region of a substrate. These improvements may reduce film peeling on a substrate, and may limit downstream contamination.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing chamber comprising:
a showerhead; and
a substrate support characterized by a first surface facing the showerhead, the first surface configured to support a semiconductor substrate, wherein the substrate support defines a recessed pocket centrally located within the first surface, the recessed pocket defined by an outer radial wall characterized by a height from the first surface within the recessed pocket greater than or about 150% of a thickness of the semiconductor substrate.

2. The semiconductor processing chamber of claim 1, wherein the outer radial wall is characterized by a height from the first surface within the recessed pocket that is less than or about 500% of a thickness of the semiconductor substrate.

3. The semiconductor processing chamber of claim 1, wherein the outer radial wall is characterized by an angle relative to the first surface of the substrate support of less than or about 90°.

4. The semiconductor processing chamber of claim 1, wherein the outer radial wall is characterized by an angle relative to the first surface of the substrate support of greater than or about 60°.

5. The semiconductor processing chamber of claim 1, wherein the outer radial wall is characterized by a radius that is less than or about 102% of a radius of the semiconductor substrate.

6. The semiconductor processing chamber of claim 1, wherein the outer radial wall is formed by the substrate support or an annular member extending about the substrate support.

7. The semiconductor processing chamber of claim 6, wherein the annular member is configured to extend radially inward past an outer radius of the semiconductor substrate, and wherein the annular member extends inward a distance of less than or about 2% of the outer radius of the semiconductor substrate.

8. The semiconductor processing chamber of claim 1, wherein the showerhead defines a plurality of apertures through the showerhead, and wherein the showerhead is configured to operate as a plasma-generating electrode.

9. The semiconductor processing chamber of claim 8, wherein a subset of the plurality of apertures are characterized by a cylindrical shape through the showerhead.

10. The semiconductor processing chamber of claim 9, wherein a subset of the plurality of apertures are at least partially characterized by a flare extending to a first surface of the showerhead, the first surface of the showerhead facing the first surface of the substrate support.

11. A method of controlling deposition uniformity, the method comprising:
depositing one or more layers of material on a semiconductor substrate within a semiconductor processing chamber, the semiconductor processing chamber comprising a showerhead and a substrate support, wherein the showerhead defines a plurality of apertures through the showerhead, and wherein at least a subset of the apertures are characterized by a cylindrical shape through the showerhead;
identifying a region of non-uniformity in film thickness of the one or more layers of material;
producing a revised showerhead defining a plurality of apertures through the showerhead, wherein the producing comprises adjusting apertures of the showerhead associated with deposition at the region of non-uniformity on the semiconductor substrate; and
depositing one or more layers of the material on a semiconductor substrate within a semiconductor processing chamber including the revised showerhead, wherein the one or more layers of material are characterized by increased uniformity relative to the region of non-uniformity identified.

12. The method of controlling deposition uniformity of claim 11, wherein the region of non-uniformity is characterized by a reduced film thickness, and wherein adjusting apertures of the showerhead comprises increasing an aperture density at a radius of the showerhead associated with deposition at the region of non-uniformity on the semiconductor substrate.

13. The method of controlling deposition uniformity of claim 12, wherein increasing an aperture density at a radius of the showerhead associated with deposition at the region of non-uniformity on the semiconductor substrate comprises at least doubling the number of apertures about the radius of the showerhead.

14. The method of controlling deposition uniformity of claim 11, wherein the region of non-uniformity is characterized by a reduced film thickness, and wherein adjusting apertures of the showerhead comprises exchanging apertures characterized by a cylindrical shape with apertures characterized by a flare extending to a first surface of the showerhead, the first surface of the showerhead configured to face the first surface of the substrate support, at a radius of the showerhead associated with deposition at the region of non-uniformity on the semiconductor substrate.

15. The method of controlling deposition uniformity of claim 14, wherein the region of non-uniformity in film thickness of the one or more layers of material is located proximate an edge of the semiconductor substrate.

16. A semiconductor processing chamber comprising:
a showerhead defining a plurality of apertures through the showerhead, wherein at least a subset of the apertures are characterized by a cylindrical shape through the showerhead; and
a substrate support characterized by a first surface facing the showerhead, the first surface configured to support a semiconductor substrate, wherein the substrate support defines a recessed pocket centrally located within the first surface, the recessed pocket defined by an outer radial wall characterized by an angle relative to the first surface of the substrate support of less than or about 90°.

17. The semiconductor processing chamber of claim 16, wherein the outer radial wall is characterized by an angle relative to the first surface of the substrate support of greater than or about 60°.

18. The semiconductor processing chamber of claim 16, wherein the outer radial wall is characterized by a height from the first surface within the recessed pocket greater than or about 150% of a thickness of the semiconductor substrate.

19. The semiconductor processing chamber of claim 16, wherein the outer radial wall is characterized by a height from the first surface within the recessed pocket that is less than or about 500% of a thickness of the semiconductor substrate.

20. The semiconductor processing chamber of claim 16, wherein a subset of the plurality of apertures are at least partially characterized by a flare extending to a first surface of the showerhead, the first surface of the showerhead facing the first surface of the substrate support.
